(19) United States
(12) Patent Application Publication
(10) Pub. No.: US 2007/0249156 A1
(43) Pub. Date: Oct. 25, 2007

(54) METHOD FOR ENABLING HARD MASK FREE INTEGRATION OF ULTRA LOW-K MATERIALS AND STRUCTURES PRODUCED THEREBY

(76) Inventors: Griselda Bonilla, Fishkill, NY (US); Stephen M. Gates, Ossining, NY (US); Shom Ponoth, Fishkill, NY (US); Satyanarayana V. Nitta, Poughquang, NY (US); Sampath Purushothaman, Yorktown Heights, NY (US)

Correspondence Address: IBM CORPORATION, T.J. WATSON RESEARCH CENTER, P.O. BOX 218, YORKTOWN HEIGHTS, NY, 10598, US

(21) Appl. No.: 11/672,608

(22) Filed: Feb. 8, 2007

Related U.S. Application Data
(60) Provisional application No. 60/793,478, filed on Apr. 20, 2006.

(51) Int. Cl. H01L 21/4763

(52) U.S. Cl. 438/622

(57) ABSTRACT

A method is described for the repair of process induced damage sustained by low-k organosilicate dielectrics as a result of reactive ion etch, resist strip, wet clean and CMP operations in a hard mask free integration of these dielectrics into microelectronic interconnect structures incorporating a dielectric cap which is an etch stop and barrier layer. In situ reaction of the damaged regions with a suitable silylation agent just prior to a passivation barrier cap deposition is proposed as the most efficacious means to repair all the damage sustained by the dielectric. Variations of this method which include ex situ rather than in situ silylation are also described for use with hard mask free integration with selective barrier caps.

### FIELD OF THE INVENTION

This invention pertains to the very high performance microelectronic chips used in computers, microprocessors, microcontrollers, sensors, communication devices and the like. In particular, the inventive structures described herein pertain to the interconnect wiring networks on such chips, significantly reducing the signal propagation delay associated with these wires. The inventive methods detailed and claimed provide the chemistry and method required to recover the dielectric properties of low dielectric constant dielectrics in integrated structures after they have been rendered hydrophilic by plasma exposures and CMP or wet clean operations encountered during processing. This enables the successful integration of these materials.

### BACKGROUND OF THE INVENTION

High performance microprocessor, microcontroller, and communication chips require very high speed interconnects between the active transistor devices that are used to perform the various functions such as logical operations, storing and retrieving data, providing control signals and the like. With the progress in the transistor device technology leading to the present ultra large scale integration, the overall speed of operation of these advanced chips are beginning to be limited by the signal propagation delay in the interconnection wires between the individual devices on the chips. The signal propagation delay in the interconnects is dependent on the RC product wherein, R denotes the resistance of the interconnect wires and C represents the overall capacitance of the interconnect scheme in which the wires are embedded. Use of copper instead of Al as the interconnect wiring material has allowed the reduction of the resistance contribution to the RC product. The current focus in the microelectronics industry is to reduce interconnect capacitance by the use of lower dielectric constant (k) insulators in building the multilayered interconnect structures on chips.

One method of creating interconnect wiring network on such small a scale is the dual damascene (DD) process schematically shown in FIG. 1. In the standard DD process, an intermetal dielectric (IMD), shown as two layers 1110, 1120 is coated on the substrate 1100, FIG. 1a. The via level dielectric 1110 and the line level dielectric 1120 are shown separately for clarity of the process flow description. In general, these two layers can be made of the same or different insulating films and in the former case applied as a single monolithic layer. A hard mask layer or a layered stack 1130 is optionally employed to facilitate etch selectivity and to serve as a polish stop. The wiring interconnect network consists of two types of features: line features that traverse a distance across the chip, and the via features which connect lines in different levels of interconnects in a multilevel stack together. Historically, both layers are made from an inorganic glass like silicon dioxide (SiO₂) or a fluorinated silica glass (FSG) film deposited by plasma enhanced chemical vapor deposition (PECVD).

In the dual damascene process, the position of the lines 1150 and the vias 1170 are defined lithographically in photoresist layers 1500 and 1510 respectively, FIGS. 1b and 1c, and transferred into the hard mask and IMD layers using reactive ion etching processes. The process sequence shown in FIG. 1 is called a “line-first” approach. After the trench formation, lithography is used to define a via pattern 1170 in the photoresist layer 1510 and the pattern is transferred into the dielectric material to generate a via opening 1180, FIG. 1d. The dual damascene trench and via structure 1190 is shown in FIG. 1e after the photoresist has been stripped. This recessed structure 1190 is then coated with a conducting liner material or material stack 1200 that serves to protect the conductor metal lines and vias and serve as an adhesion layer between the conductor and the IMD. This recess is then filled with a conducting fill material 1210 over the surface of the patterned substrate. The fill is most commonly accomplished by electroplating of copper although other methods such as chemical vapor deposition (CVD) and other materials such as Al or Au can also be used. The fill and liner materials are then chemical-mechanical polished (CMP) to be coplanar with the surface of the hard mask and the structure at this stage is shown in FIG. 1f. A capping material 1220 is deposited as a blanket film, as is depicted in FIG. 1g to passivate the exposed metal surface and to serve as a diffusion barrier between the metal and any additional IMD layers to be deposited over them. Silicon nitride, silicon carbide, and silicon carbonitride films deposited by PECVD are typically used as the capping material 1220. This process sequence is repeated for each level of the interconnects on the device. Since two interconnect features are simultaneously defined to form a conductor in-laid within an insulator by a single polish step, this process is designated a dual damascene process.

In order to lower the capacitance, it is necessary to use lower k dielectrics such as PECVD or spin-on organosilicates which have k values in the 2.5 to 3.1 range instead of the PECVD silicon dioxide based dielectrics (k=3.6 to 4.1). These organosilicates have a silica like backbone with alkyl or aryl groups attached directly to the Si atoms in the network. Their elemental compositions generally consist of Si, C, O, and H in various ratios. The C and H are most often present in the form of methyl groups (—CH₃). The primary function of these methyl groups is to add hydrophobicity to the materials. A secondary function is to create free volume in these films and reduce their polarizability. The k value can be further reduced to 2.2 (ultra low k) and even below 2.0 (extreme low k) by introduction of porosity in these insulators. For the purpose of brevity, we shall refer to these ultra low k and extreme low k materials collectively as very low k materials in this document. Although a tunable range of k values is possible with this set of very low k materials there are several difficulties in integrating these materials with copper interconnects by the dual damascene process described above or by any other variation of the dual damascene process. The chief difficulty is that the organosilicate-based materials are very sensitive to plasma exposures because of the relative ease of oxidation or cleavage of the Si-organic group linkage (for example, Si-methyl) which results in the formation of silanol (Si—OH) groups in the film through a potential reaction with moisture in the ambient. Silanols absorb H₂O and hence increase the dielectric constant and the dielectric loss factor of the film significantly thus negating the performance benefits expected from the very low k films. They also increase the electrical leakage in the film and thus create a potentially unreliable interconnect structure. Since reactive ion etch and plasma etch are key steps required in the formation of the dual damascene trench and via structure as described above and in the removal of photoresists used in patterning the very low k materials, it is very difficult if not impossible to avoid plasma damage of this class of films during a dual damascene integration. In an earlier pending application (US Patent application 2005/0106762A1 dated May 19, 2005 with priority from provisional application 60/499856 dated Sep. 3, 2003, the teaching of which is incorporated herein by reference), methods and chemistries to enable the repair of such plasma damage using a process termed silylation has been described. The method entails reacting certain silylation agents with the Si—OH groups in the plasma damaged ULK films to replace the Si—OH groups with Si—O—Si—R groups where R is an organic functional group. This restores the hydrophobicity and the desirable low dielectric constant properties of the ULK film.

For ease of integration of these low-k dielectric materials, thin dense hard mask films (˜500 A) are usually deposited atop the dielectric surface either as an etch-stop or CMP-stop material. The main drawback of the addition of a thin dense hard mask film is its impact on the overall effective dielectric constant (keff) of the integrated build. To reduce keff and make low-k integration a simpler and hence, more manufacturable process, it is desirable to polish off the hard mask during CMP. This introduces new issues related to the effect of CMP chemistries and processing on the surface of the porous film. In particular, during the CMP process, when the dielectric is exposed to aqueous media, and especially under basic conditions, a nucleophilic attack of the siloxane bond results in the formation of two silanols. Moreover, above a pH of 2, dissolution of the siloxane network is catalyzed by OH— ions that increase the coordination of Si above 4, therefore weakening the siloxane bonds in the network. The dissolution rate increases with pH and is very high in basic conditions. In this case, while silanols form as a result of a chemical attack of the IMD surface layer, it has the same effect of increasing the effective dielectric constant of the integrated structure as in the case of plasma damage.

Another source of damage to this class of films occurs during the in situ copper pre-cleaning process prior to cap deposition. Specifically, a NH₃— or H₂— based plasma (for example) is used to successfully clean the surface of the metal fill by reducing the oxide material thereon. While the plasma is effective in cleaning the Cu surface and improving the electromigration and stress migration for these structures, the pre-clean step causes severe damage to the exposed IMD layer. This affects the integrity of the film, causing a degradation of the dielectric constant k, loss, and leakage of the film. This issue is specifically severe in the case of a hard mask free process flow wherein the IMD surface is directly exposed to the plasma preclean as there is no hard mask layer over it to protect it from this exposure. Therefore, performing silylation after the CMP process, post plasma pre-clean, is extremely advantageous in that the silylating agent can restore the dielectric properties of the film after the last damaging exposure of the dielectric has been sustained. Upon delivering the silylating agent to the structure, it can diffuse from the top surface of the dielectric into the bulk of the film, extending to the sidewalls of the formed via and line structure. Hence, the IMD damage caused by all the earlier operations in the process flow (i.e., RIE, resist strip, CMP, etc.) can be repaired in one silylation step that is performed preferably in situ as an integral part of the cap deposition process.

It is therefore an object of this invention to disclose a set of process flows as well as a class of silylating agents used to completely restore the hydrophobicity, low dielectric constant, low dielectric loss, high dielectric breakdown, and dielectric reliability of the porous low k inter-metal dielectric materials post process exposure without yielding a corrosive byproduct. It is a further object of this invention to disclose a method by which the silylating agents of this invention can be introduced such that they penetrate the bulk of the porous low k material and recover these properties.

The advantage of this invention is that the material choice for ultra low k intermetal dielectrics need not be constrained by a consideration of the effects of plasma and wet cleaning damage, CMP, and cap deposition, because they can be restored to their original properties after they have sustained all such damage, by using repair chemistries identified in the cited patent application #: US2005/0106762 A1 the teaching of which is incorporated herein by reference. Further, the availability of a reliable method to recover the properties of films offers a greater opportunity to explore a broader set of process options for reactive ion etch (RIE), resist strip, CMP chemistries and processing, as well as for cap preclean and deposition processes. These operations are all required in a standard dual damascene build to yield a functional and reliable interconnect structure and can in turn result in more robust and lower cost processing.

### SUMMARY OF THE INVENTION

A broad aspect of the present invention is a method for a vapor phase silylation repair for at least one ultra low k dielectric film comprising: providing an in situ cap deposition process subsequent to all process seps that cause damage to said ultra low k dielectric film have occurred in a hard mask free integration process by silylation in situ before the cap dielectric deposition to repair all the cumulative damage and sealing the repaired dielectric with the cap layer.

Another broad aspect of the present invention is a vapor phase silylation repair method for ultra low k ILD films, practiced preferably in situ in a cap deposition process chamber right after all the damaging steps to the ultra low k dielectric have occurred in a hard mask free integration scheme. These damaging steps are for example: RIE, resist strip, wet cleans, CMP and plasma preclean before a post CMP cap deposition. By doing the silylation in situ just before the cap dielectric deposition step, repair of all the cumulative damage and sealing the repaired dielectric with the cap layer is possible.

### BRIEF DESCRIPTION OF THE DRAWINGS

These and other aspects, features, and advantages of the present invention will become apparent upon further consideration of the following detailed description of the invention when read in conjunction with the attached drawing figures, in which:

FIG. 1a to FIG. 1g illustrate the process flow for a standard dual damascene integration scheme. (Prior art)

FIG. 2 is a schematic diagram illustrating the effect of plasma exposure and silylation on the chemistry of the very low k material.

FIG. 3a is a schematic diagram of the damage that the low-k dielectric sustains during the reactive ion etch and ash processes that typically take place in a standard dual damascene integration scheme;

FIG. 3b is a schematic diagram of the additional damage that the low-k dielectric sustains after exposure to chemical mechanical polish process and slurries, and after the plasma preclean processes that take place prior to the PECVD barrier deposition;

FIG. 3c illustrates the diffusion of the silylating agent into the IMD as it repairs all damaged layers within the low-k dielectric films of the structure shown in FIG. 3b.

FIG. 3d shows the structure after the completion of the final step—the deposition of the dielectric etch stop and barrier layer by PECVD in situ just after the silylation repair is complete;

FIG. 4a is a schematic diagram of the damage that the low-k dielectric sustains during the reactive ion etch and ash processes that typically take place in a standard dual damascene integration scheme;

FIG. 4b is a schematic diagram of the additional damage that the low-k dielectric sustains after exposure to chemical mechanical polish process and slurries for an integration scheme that does not require an in situ plasma preclean prior to barrier deposition (for example, an integration scheme with a selective metal barrier);

FIG. 4c illustrates the diffusion of the silylating agent into the IMD as it repairs all damaged layers within the low-k dielectric films of the structure shown in FIG. 4b.

FIG. 4d shows the structure after the completion of the final step—the deposition of the dielectric etch stop and barrier layer by PECVD in situ just after the silylation repair is complete.

### DETAILED DESCRIPTION OF THE INVENTION

An exemplary embodiment of this invention (called embodiment 1 from now on) discloses the use of a novel class of silylating agents applied to a film after the plasma pre-clean processing used prior to a cap deposition in order to recover the dielectric properties and therefore enable a hard mask free integration scheme. Further, exemplary embodiment 1 of this invention also discloses a method by which these silylation agents are introduced into the process to ensure that the external surface, as well as the bulk (including sidewall regions of the dielectric adjacent to the metal features and all the interior pore walls) of the porous low k material is rendered hydrophobic. Finally, a second embodiment of this invention discloses process variations that will make the process applicable for alternative integration schemes.

### Exemplary Embodiment 1

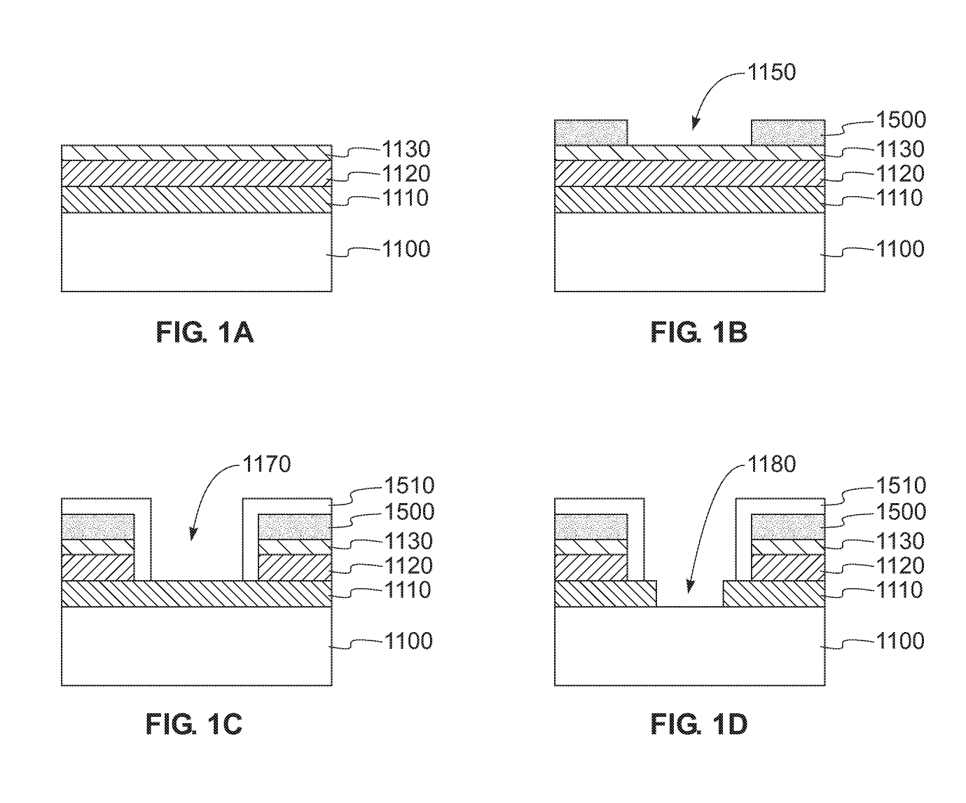

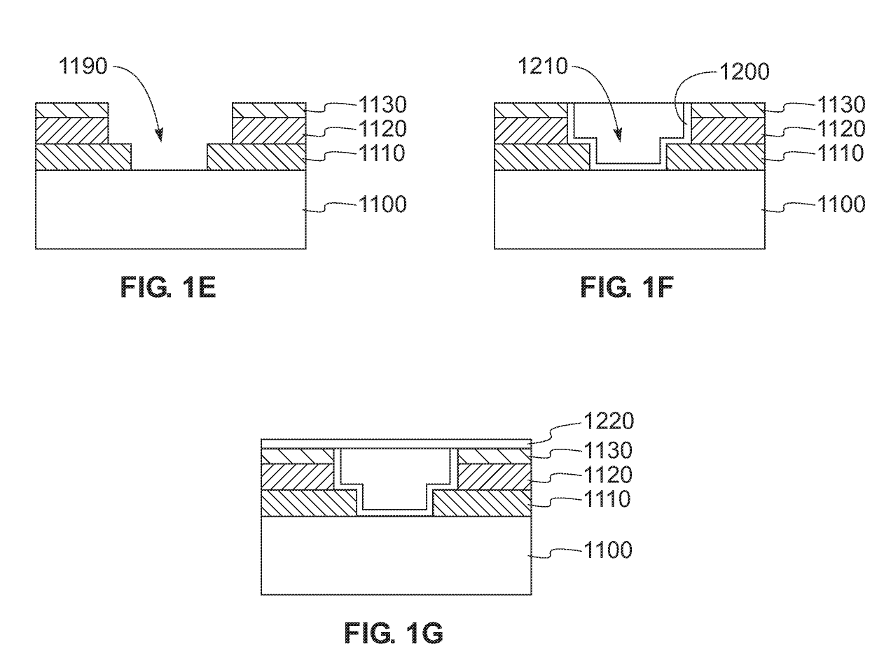

In embodiment 1 of this invention, the silylating agents of this invention are introduced into the single or dual damascene process flow for building an interconnect structure after the chemical-mechanical polish of the conductive liner and fill, and before the cap deposition process. Specifically, the silylating agents are introduced in-situ in a CVD chamber after the plasma preclean step used to clean the metal surface of oxides and CMP slurry residuals, and prior to the cap material deposition. If a dual damascene scheme such as the one depicted in FIG. 1 is used, the silylating agent of the present invention is introduced between processing steps depicted in FIGS. 1f and 1g. It should be noted that the silylating agents such as the ones detailed in the patent application US2005/0106762 the teaching of which is incorporated herein by reference can be used in interconnect structures which utilize porous organosilicates as line and via level dielectrics. These porous dielectrics can also be used as line level dielectrics alone in combination with other porous or dense organosilicates, SiO₂, FSG, FTEOS, fluorinated or non-fluorinated organic polymers used as via level dielectrics.

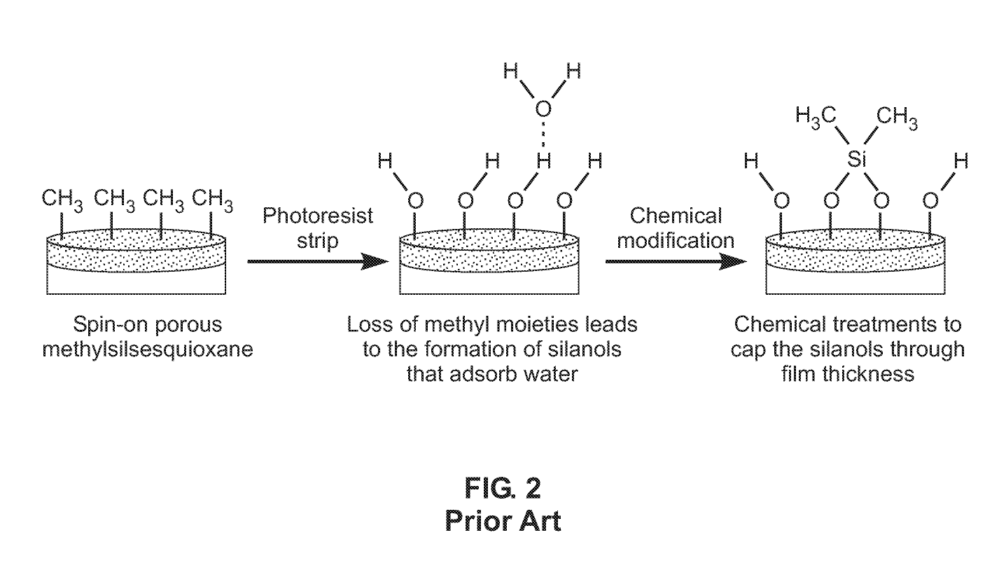

The schematic in FIG. 2 demonstrates how the silylating agents used in this invention succeed in replenishing the organic moieties in the low k organosilicate films following their removal during typical process plasma exposures such as resist strip operations. Silanol formation as a result of the hydrolysis of the siloxane bonds described earlier in the present application can also be reversed in the same fashion.

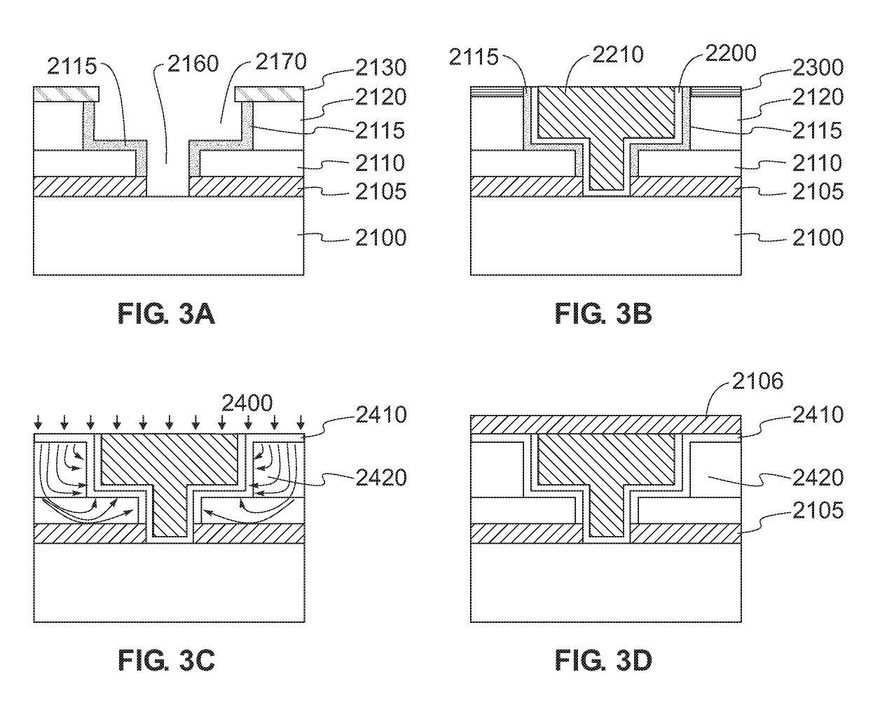

The process flow of embodiment 1 of this invention is pictorially depicted in FIGS. 3a through 3d. FIG. 3a depicts a partially processed interconnect structure analogous to the structure shown in FIG. 1e. The layers are numbered as follows. The structure depicted comprises a substrate 2100 with a passivation layer 2105 that serves to protect interconnects or devices (not shown in figure) that may be optionally present on the substrate. FIG. 3a further shows a via level dielectric 2110 and line level dielectric 2120 and a sacrificial hard mask layer 2130. Dielectrics 2110 and 2120 can be selected, for example, from a porous organosilicate glass material, a porous silsesquioxane, a porous SiCOH dielectric deposited by PECVD, or a porous carbon doped oxide. Layers 2110 and 2120 can be made of the same material or different materials. Layer 2120 can be optionally chosen from silicon oxide, fluorinated silicon oxide, dense SiCOH and the like. Layer 2130 is chosen to be removable during the metal CMP step as will be described later. Layer 2130 can be made of silicon oxide, silicon carbide and the like. Via hole 2160 and line trench 2170 are shown patterned in the layers producing the interconnect cavities. Such a structure can be fabricated using lithography and RIE processes known in the dual damascene patterning process described earlier in connection with FIGS. 1a through 1e. Such a process involves plasma exposure of the dielectrics 2110 and 2120 during reactive ion etch patterning and photoresist stripping steps required for producing the cavities 2160 and 2170, leading to plasma damaged sidewall regions 2115.

The interconnect cavities are then coated with a conducting liner material or material stack 2200 that serves to protect the conductor metal lines and vias and serve as an adhesion layer between the conductor and the IMD layers. The interconnect cavities are then filled with a conducting fill material 2210 over the surface of the patterned substrate. The fill is most commonly accomplished by electroplating of copper although other methods such as chemical vapor deposition (CVD) and other materials such as Al or Au can also be used. The fill and liner materials are then chemical-mechanical polished (CMP) along with the sacrificial hard mask layer 2130. As a result, the top surface of the line level dielectric 2120 is exposed to CMP processing and hence gets modified resulting in a damaged layer 2300. The resulting structure with the conductive fill 2210 coplanar with the damage layer 2300 is shown in FIG. 3b.

In the next step, the substrate with the interconnect structure as shown in FIG. 3b is introduced into a chamber that is used for the in situ plasma preclean of the surface of the conductive fill 2210 and plasma enhanced chemical vapor deposition of passivation dielectrics such as silicon nitride, silicon carbide, silicon carbonitride and the like. Next, the in situ plasma preclean of fill metal 2210 is performed using a plasma comprising suitable gases. Typically mixtures of reducing and inert gases such as hydrogen, ammonia, helium, and nitrogen are used for this step. Any plasma condition may be used within the invention for the step we call the “plasma preclean”. An example condition is to use ammonia or hydrogen mixed with He or nitrogen at a flow rate of 1 to 2 standard liters per minute, at a pressure of 3 torr, with an RF power of 500 Watts, with the substrate temperature 350° C. for a time of 5 to 30 seconds. This process can further modify and damage the regions 2300 of the dielectric 2120 and potentially introduce dangling bonds due to plasma scission processes. At this juncture, the silylating agent is introduced into the chamber in vapor form using a suitable injection means and maintained at a controlled vapor pressure within the chamber. The silylation agents used can include any mono-, di-, and tri-functional agents with alkoxy, chloro, amino and silazane reactive groups as described in patent application US2005/0106762 the teaching of which is incorporated herein by reference. The substrate is held at a selected temperature in the range of room temperature to 450 C. In particular, this step is preferably performed at about 150 C for times ranging from 30 seconds to 60 minutes using vapor phase delivery of the silylation agent to the substrate that contains the interconnect structure. A range of pressures may be used during this silylation step, including the wide range from about 0.001 to 100 torr. Preferably, the pressure is in the range 1 to 10 torr.

As shown by the short and wavy arrows in FIG. 3c, the silylation agent vapors 2400 penetrate into the dielectric and react and repair the damage in regions originally denoted as 2115 and 2300 in FIG. 3b, resulting in repaired regions 2410 and 2420 as shown in FIG. 3c. The duration of the silylation reaction will be dependent on the reactivity of the agent used and the dielectrics involved but will typically be in the range of 30 seconds to 1 hour. The silylation can be carried out any temperature between room temperature and 450 C and may be followed by an optional anneal step at a higher temperature up to 450 C. The silylation repaired regions 2410 and 2420 will become hydrophobic and will have properties comparable to the pristine undamaged film as a result of elimination of silanols and repair of dangling bonds resulting from in situ plasma cleaning. The last step in the present method is to deposit the PECVD dielectric cap 2106 in situ just after the silylation repair is complete, resulting in the structure shown in FIG. 3d. The cap 2106 is intended to function as a passivation layer and diffusion barrier for the interconnect metal; additionally it can also be used as an etch stop layer during the optional build of additional interconnect layers atop the ones shown in FIG. 3. Materials suitable for the cap layer 2106 are by example chosen from but not limited to silicon nitride, silicon carbide, silicon carbonitride and combinations thereof. The inter-metal dielectric layers are thus silylated and repaired in situ and immediately after the last damaging step (in situ preclean) occurs, thus providing a more reliable interface between the cap 2106 and the repaired top region 2410 of the dielectric 2120. Additionally, the repaired sidewall region 2420 is also produced concurrent with region 2410 and sealed off by the cap layer 2106. Silylation performed in a PECVD tool cluster allows for reduced process time and tooling costs since all steps are carried out in the same process flow in the same tool cluster, as opposed to stand alone vapor silylation, liquid silylation or supercritical CO₂ based silylation all of which require an ex-situ process and hence the addition of extra tools and steps in the process flow.

Preferred silylating agents to effect this repair are generally called aminosilanes and they will be referred to as such for the rest of this invention document. Agents can be chosen from, but not restricted to, the ones described in US Patent application 2005/0106762A1 the teaching of which is incorporated herein by reference. Preferred silylating agents include, but are not limited to bis(dimethylamino)dimethylsilane, bis(dimethylamino)methylsilane, trimethylaminodimethylsilane, and tris(dimethylamino)methylsilane. Alkoxysilanes such as diethoxymethylsilane, diethoxydimethylsilane as well as tetramethylcyclotetrasiloxane (TMCTS) can also be used efficaciously to achieve repair by silylation.

It is very important for the purpose of this invention to handle the silylating agent in a substantially moisture free ambient since any moisture that might be present could reduce the efficacy of the silylation reaction. Storage and delivery methods will have to include appropriate precautions to enable exclusion of moisture from the agent. Such methods are feasible and compatible with the type of tooling described herein. Although the method is exemplified with a PECVD chamber and cluster tooling, other chambers used in semiconductor industry for chemical vapor deposition (CVD) or atomic layer deposition (ALD) can be employed within the scope of this invention. All of these chambers are attractive since they are designed to handle the introduction of vapor species in a substantially pure form free of moisture and other contaminants and allow substrate heating. Moreover, in a cluster tool set-up, the silylation process can be optionally set up in its own chamber. In this case, the silylating agent is bled into the dedicated chamber in the cluster, with an optional carrier gas at operating temperatures ranging from 20° C. to 450° C. for a duration ranging from 30 seconds to an hour or more. A range of pressures may be used during this silylation step, including the wide range from about 0.001 to 100 torr. Preferably, the pressure is in the range 1 to 10 torr. Typically a pressure between 1 to 10 torr of the agent can usually be achieved with a liquid mass flow rate of the silylating agent between 10 to 5000 milligrams per minute into the process chamber. Within the invention, a range of pressures may be used during this silylation step depending on the agents of choice, including the range from about 0.001 to 100 torr.

Following vapor phase silylation, an optional hot plate bake or other thermal treatment up to a temperature of 450° C. can be employed. Most importantly, the last step that causes damage to the porous IMD, namely the plasma preclean step, is typically performed in the typical vacuum processing tool cluster. It is therefore advantageous to incorporate the silylation repair in the same cluster so that the damage can be repaired in situ prior to capping with a barrier dielectric. Such a tool cluster enables the transfer of the substrates from the plasma preclean chamber to the silylation chamber and then to a dielectric etch stop and barrier layer deposition chamber (if these are chosen to be distinct chambers in the cluster) without exposing the substrates to the external ambient and thus excluding moisture from the processing. When introduced in this configuration, the silylating agent can easily repair the surface damage in the IMD caused by the preclean and by CMP and also diffuse into the bulk IMD layer to repair the entire film, including the sidewalls of the dual damascene structure that are damaged during etch/ash processing. This process ensures a more reliable interface between the cap/IMD interface as well as a lower keff of the integrated structure. FIG. 3d shows the structure after formation of the dielectric cap layer 2106.

The method of embodiment 1 may be summarized as a method of fabricating an interconnect structure on a substrate comprising the following steps:
a) providing a structure on said substrate comprising a dielectric having a dielectric constant of less than 3.0, said dielectric having at least one etched opening located therein;
b) filling said at least one etched opening with at least one conductive material and then planarizing said at least one conductive material utilizing a CMP slurry to provide a planarized structure having an upper surface of said conductive material nominally coplanar with an upper surface of said dielectric, said dielectric being exposed to said CMP slurry;
c) subjecting said planarized structure to a plasma preclean process; and
d) exposing said planarized structure to a silylating repair agent which is a derivative of a silane material with at least one silicon atom in its molecular make up and wherein at least one of the hydrogen atoms is substituted with an alkoxy-, chloro-, amino- or silazane functional group
e) and forming a dielectric cap layer on said planarized structure.

### Exemplary Embodiment 2

Embodiment 1 shows the efficacy of performing vapor phase silylation subsequent to plasma preclean within the same CVD chamber or cluster tool. Embodiment 1 also shows that the introduction of silylating agents, after all the damaging exposures to the IMD have been sustained, effectively restores the properties of the entire IMD layer. However, there exist other hard mask-free integration schemes that do not require a plasma preclean. For example, with the use of selective metal caps or barriers (CoWP or CuSiN for example) an ex situ solvent preclean might be implemented instead before and optionally after the deposition of those layers. An optional dielectric cap layer (as an etch stop and barrier) may be deposited after the selective caps are formed to enable build of additional interconnect levels. The selective cap may obviate the need for an additional in situ plasma preclean step prior to the deposition this optional dielectric etch stop and barrier layer, in which case the IMD layer does not sustain further damage due to plasma processing. An optional ex situ wet cleaning may instead be used prior to transfer of the substrates to the dielectric etch stop and barrier deposition step. For these and similar cases, an alternative method of application of the silylating agent can be performed subsequent to the direct polish of the IMD layer during the CMP step and any optional wet clean steps referred to above. For this particular application, the silylation can be performed in spin-on, liquid, vapor, or supercritical CO₂ media, for example, as described fully in Patent US2005/0106762. Further, the application of the silylating agent at this process step allows for the repair of any wet clean damage, CMP damage (caused by hydrolysis of the siloxane network) as well as RIE and resist strip damage repair (caused by removal of organic moieties from the IMD layer during resist strip operations for example) in the same manner as described in embodiment 1 and illustrated in FIG. 3c. This is because the damaged surface of the IMD is exposed after the polishing step due to the complete removal of the hard mask layer and the silylating agent can repair the surface of the IMD and readily penetrate into the bulk of the IMD to fully restore its properties.

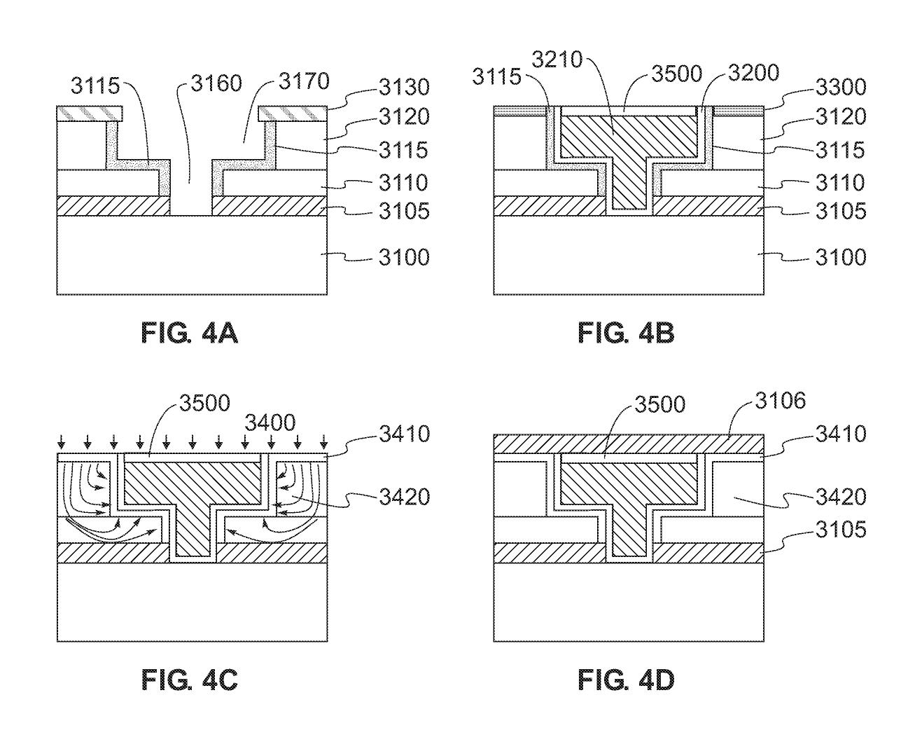

The process flow of embodiment 2 of this invention is pictorially depicted in FIGS. 4a through 4d. FIG. 4a depicts a partially processed interconnect structure analogous to the structure described in FIG. 3a. The layers are numbered as follows. The structure depicted comprises a substrate 3100 with a passivation layer 3105 that serves to protect interconnects or devices (not shown in figure) that may be optionally present on the substrate. FIG. 4a further shows a via level dielectric 3110 and line level dielectric 3120 and a sacrificial hard mask layer 3130. Layer 3130 is chosen to be removable during the metal CMP step as will be described later. It should be noted that the material choices listed for layers 2110, 2120 and 2130 of FIG. 3 in the description of embodiment 1 earlier in this application apply to layers 3110, 3120 and 3130 respectively in the present embodiment shown in FIG. 4. Via hole 3160 and line trench 3170 are shown patterned in the layers producing the interconnect cavities. Such a structure can be fabricated using lithography and RIE processes known in the dual damascene patterning process described earlier in connection with FIGS. 1a through 1e. Such a process involves plasma exposure of the dielectrics 3110 and 3120 during reactive ion etch patterning and photoresist stripping steps required for producing the cavities 3160 and 3170, leading to plasma damaged sidewall regions 3115. The interconnect cavities are then coated with a conducting liner material or material stack 3200 that serves to protect the conductor metal lines and vias and serve as an adhesion layer between the conductor and the IMD layers. The interconnect cavities are then filled with a conducting fill material 3210 over the surface of the patterned substrate. The fill is most commonly accomplished by electroplating of copper although other methods such as chemical vapor deposition (CVD) and other materials such as Al or Au can also be used. The fill and liner materials are then chemical-mechanical polished (CMP) along with the sacrificial hard mask layer 3130. As a result, the top surface of the line level dielectric 3120 is exposed to CMP processing and hence gets modified resulting in a damaged layer 3300. The resulting structure with the conductive fill 2210 coplanar with the damage layer 3300 is shown in FIG. 4b.

In the next step, the substrate with the interconnect structure as shown in FIG. 4b is introduced into a tool designated for deposition of a selective metal or dielectric barrier film 3500. Since the selective metal or dielectric cap processes highlighted in this embodiment do not require in situ plasma preclean of the surface of the conductive fill 3210, the top surface of the line level dielectric 3120 is not subjected to further plasma processing damage. The selective cap can be either a CoWP metal cap or a dielectric barrier cap such as CuSiN. A suitable ex-situ solvent preclean can be implemented to clean the surface of the conductive fill 3210 prior to and optionally after the formation of cap 3500. Next, the interconnect structure shown in 4b is introduced into a chamber that is typically used for plasma enhanced chemical vapor deposition of passivation dielectrics such as silicon nitride, silicon carbide, silicon carbonitride and the like.

At this juncture, the silylating agent is introduced into the chamber in vapor form using a suitable injection means and maintained at a controlled vapor pressure within the chamber. The silylating agent is bled into the dedicated chamber with an optional carrier gas at operating temperatures ranging from 20° C. to 450° C. for a duration ranging from 30 seconds to an hour or more. Typical reaction environment for vapor silylation can vary but a preferred range of pressure between 1 to 10 torr of the agent can usually be achieved with a liquid mass flow rate of the silylating agent between 10 to 5000 milligrams per minute into the process chamber. Within the invention, a range of pressures may be used during this silylation step depending on the silylation agent used, including the range from about 0.001 to 100 torr. Preferred silylating agents to effect this repair are generally called aminosilanes and they will be referred to as such for the rest of this invention document. Agents can be chosen from, but not restricted to, the ones described in US Patent application 2005/0106762A1 the teaching of which is incorporated herein by reference. Preferred silylating agents include, but are not limited to bis(dimethylamino)dimethylsilane, bis(dimethylamino)methylsilane, trimethylaminodimethylsilane, and tris(dimethylamino)methylsilane. Alkoxysilanes such as diethoxymethylsilane, diethoxydimethylsilane as well as tetramethylcyclotetrasiloxane (TMCTS) can also be used efficaciously to achieve repair by silylation.

Optionally, the step of silylation repair can be performed in a separate reactor with the agent introduced as a vapor, as a solution by a spin on coating method, as a liquid bath in which the substrates are immersed or as a mixture with supercritical CO₂ and suitable co-solvents and pressurized conditions. When liquid media are used for silylation, an optional agitation process can be incorporated to facilitate enhanced rates of reaction.

As shown by the short and wavy arrows in FIG. 4c, the silylation agent in liquid, vapor or a supercritical fluid medium 3400 penetrates into the dielectric and reacts and repairs the damage in regions originally denoted as 3115 and 3300 in FIG. 4b, resulting in repaired regions 3410 and 3420 as shown in FIG. 4c. The duration of the silylation reaction will be dependent on the reactivity of the agent used and the dielectrics involved but will typically be in the range of 30 seconds to 1 hour. The silylation can be carried out any temperature between room temperature and 450 C and may be followed by an optional anneal step at a temperature up to 450 C. The silylation repaired regions 3410 and 3420 will be hydrophobic and will have properties comparable to the pristine undamaged film as a result of elimination of silanols and repair of dangling bonds resulting from plasma and CMP induced damage. The last step in the present method is to deposit the PECVD dielectric cap 3106 just after the silylation repair is complete, resulting in the structure shown in FIG. 4d. The dielectric layers are thus silylated and repaired immediately after the last damaging steps (CMP induced damage and any optional wet clean steps involved in the formation and cleaning of the selective cap layer 3500) occurs, thus providing a more reliable interface between the cap 3106 and the repaired top region 3410 of the dielectric 3 120. Additionally, the repaired sidewall region 3420 is also produced concurrent with region 3410 and sealed off by the dielectric etch stop and barrier layer 3106.

As mentioned before, the silylation repair process is performed either ex situ in a stand alone tool delivering the silylation agent in liquid, vapor or a supercritical fluid medium or in situ in a vacuum deposition processing tool cluster as described in embodiment 1. The silylation agents used can include any mono-, di-, and tri-functional agents with alkoxy, chloro, amino and silazane reactive groups as described in patent application US2005/0106762 the teaching of which is incorporated herein by reference. It is very important for the purpose of this invention to handle the silylating agent in a substantially moisture free ambient since any moisture that might be present could reduce the efficacy of the silylation reaction. Storage and delivery methods will have to include appropriate precautions to enable exclusion of moisture from the agent. If supercritical fluids such as carbon dioxide are used as the medium of delivering the silylation agent temperature, pressure and time ranges for the silylation can be as follows: Temperature: 25 C to 450° C., Pressure: 1000 to 5000 psi, Time: 30 s to 1 hour or more. The silylation agent can be directly dissolved in the supercritical fluid or be optionally mixed with co-solvent to enable increased solubility. If a liquid medium delivery of agent is used the following conditions will be preferably employed. The substrates are immersed in the liquid phase comprising the silylation agent optionally dissolved in any non-polar organic solvent with an optional agitation provided to facilitate the reaction. The optional non-polar organic solvent used should be of a low surface tension such that the pores of the dielectric can be penetrated effectively. Some examples of such solvents include but are not limited to, hexanes, heptanes, xylenes, propylene carbonates, heptanones and the like, and where it is desirable but not necessary for the solvent to have a low volatility as measured by its flash point and boiling point. The concentration of the silylation agents necessary for effective silylation can be as low as 1% by weight of the solution and as high as 100% of the liquid medium employed. In the case where such ex situ silylation repair is used, after the silylation and anneal steps are completed, the substrates are transferred to a suitable PECVD deposition tool where the dielectric etch stop and barrier layer 3106 is deposited without resorting to any in situ plasma preclean step.

The method of embodiment 2 may be summarized as a method of fabricating an interconnect structure on a substrate comprising:
a) providing a structure on said substrate comprising a porous a dielectric having a dielectric constant less than 3.0, said dielectric having at least one etched opening located therein;
b) filling said at least one etched opening with at least one conductive material, and then planarizing said at least one conductive material utilizing a CMP slurry to provide a planarized structure having an upper surface of said conductive material nominally coplanar with an upper surface of said dielectric, said upper surface of said dielectric being exposed to said CMP slurry;
c) optionally wet cleaning said upper surface of said conductive material and forming a self-aligned cap thereon
d) exposing said planarized structure to a silylating repair agent which is a derivative of a silane material with at least one silicon atom in its molecular make up and wherein at least one of the hydrogen atoms is substituted with an alkoxy-, chloro-, amino- or silazane functional group
e) forming a dielectric etch stop and barrier layer on said planarized structure.

What is claimed is:

1. A method of fabricating an interconnect structure on a substrate comprising:
providing a dielectric having a dielectric constant of less than 3.0 on said substrate, said dielectric having at least one etched opening located therein;
filling said at least one etched opening with at least one conductive material and then planarizing said at least one conductive material utilizing a CMP slurry to provide a planarized structure having an upper surface of said conductive material nominally coplanar with an upper surface of said dielectric, said upper surface of dielectric being exposed to said CMP slurry;
subjecting said planarized structure to a plasma preclean process; and
exposing said planarized structure to a silylating repair agent which is a derivative of a silane material with at least one silicon atom in its molecular make up and wherein at least one of the hydrogen atoms is substituted with an alkoxy-, chloro-, amino- or silazane functional group; and
forming a dielectric cap layer on said planarized structure.

2. A method according to claim 1 wherein said exposing and said forming are performed in a single chamber without moving said substrate.

3. A method according to claim 1 wherein said exposing and said forming are performed in separate chambers that are connected on a single cluster tool, and said exposing and said forming are performed by moving said substrate between chambers without exposure to air, moisture, or other source of oxidation.

4. A method according to claim 1 wherein said exposing is performed in a substantially moisture free and oxygen free ambient.

5. A method according to claim 1 wherein said exposing is performed with the silylation agent in the vapor phase and with said substrate held at a temperature in the range from 20 to 450 degrees C., and preferably at about 150 degrees C.

6. A method according to claim 1 wherein said exposing is performed for a time selected from the group consisting of 30 seconds to one hour and most preferably for about 60 to 300 seconds.

7. A method according to claim 1 wherein said exposing is performed using any silylating agent which is a silane derivative selected from a group including, but not limited to mono-, di-, and tri-functional silylation agents with alkoxy, chloro, amino or silazane reactive groups attached to said at least one Si atom in its molecular make up.

8. A method according to claim 7 wherein said exposing is performed using a silylating agent molecule selected from the following group: bis(dimethylamino)dimethylsilane, bis(dimethylamino)methylsilane, trimethylaminodimethylsilane, tris(dimethylamino)methylsilane, and alkoxysilanes such as diethoxymethylsilane, diethoxydimethylsilane and tetramethylcyclotetrasiloxane.

9. A method according to claim 1 wherein said dielectric is a porous organosilicate glass material, a porous silsesquioxane, a porous SiCOH dielectric deposited by PECVD, or a porous carbon doped oxide, and said at least one etched opening consists of a plurality of single or dual damascene etched openings.

10. A method according to claim 1 wherein said exposing is performed in a chamber designed for PECVD deposition using a pressure between 0.001 to 100 torr.

11. A method according to claim 1 wherein said exposing is performed in a chamber designed for PECVD deposition using a pressure preferably between 1 to 10 torr and a liquid mass flow rate of the silylating agent between 10 to 5000 milligrams per minute.

12. A method according to claim 3 wherein said cluster tool has distinct chambers for one or more of silylation, plasma pre-clean and dielectric cap, etch stop and barrier deposition processes.

13. A method of fabricating an interconnect structure on a substrate comprising:
providing a dielectric having a dielectric constant of less than 3.0 on said substrate, said dielectric having at least one etched opening located therein;
filling said at least one etched opening with at least one conductive material, and then planarizing said at least one conductive material utilizing a CMP slurry to provide a planarized structure having an upper surface of said at least one conductive material nominally coplanar with an upper surface of said dielectric, said upper surface of said dielectric being exposed to said CMP slurry;
forming a self-aligned cap on said upper surface of said conductive material;
exposing said planarized structure to a silylating repair agent which is a derivative of a silane material with at least one silicon atom in its molecular make up and wherein at least one of the hydrogen atoms is substituted with an alkoxy-, chloro-, amino- or silazane functional group;
forming an optional dielectric cap layer on said self-aligned cap and said upper surface of said dielectric.

14. A method according to claim 13 wherein said exposing is performed in a medium selected from the group consisting of a liquid, vapor and supercritical CO₂ phase.

15. A method according to claim 13 wherein said exposing is performed in liquid phase medium, using any non-polar organic solvent, with the silylating agent forming a solution in said solvent, and with said substrate immersed in said liquid phase, and with an optional use of agitation.

16. A method according to claim 13 wherein said exposing is performed in a non-polar organic solvent with a low surface tension, having a low flash point and boiling point, and wherein the concentration of the silylation agent is between 1% to 100% by weight of the solution.

17. A method according to claim 13 wherein said exposing is performed in a solvent selected from the group consisting of hexanes, heptanes, xylenes, propylene carbonates and heptanones.

18. A method according to claim 13, wherein said exposing is performed using said silylating agent dissolved in a supercritical CO₂ medium, and optionally in combination with a co-solvent, and wherein the silylation is performed in the temperature range between 25 degrees C. to 450 degrees C., and a pressure range from 1000 to 5000 psi, for a time interval from about 30 seconds to 1 hour.

19. A method according to claim 13 wherein said exposing is performed using a silylating agent which is a silane derivative selected from a group including, but not limited to mono-, di-, and tri-functional silylation agents with alkoxy, chloro, amino or silazane reactive groups attached to said at least one Si atom in its molecular make up.

20. A method according to claim 13 wherein said exposing is performed using a silylation agent molecule selected from the group consisting of bis(dimethylamino)dimethylsilane, bis(dimethylamino)methylsilane, trimethylaminodimethylsilane, tris(dimethylamino)methylsilane, and the alkoxysilanes such as diethoxymethylsilane, diethoxydimethylsilane and tetramethylcyclotetrasiloxane.

21. A method according to claim 13 wherein
said exposing and said forming are performed in a single chamber without moving said substrate;
said exposing and said forming are performed in separate chambers that are connected on a single cluster tool, and said exposing and said forming are performed by moving said substrate between chambers without exposure to air, moisture, or other source of oxidation;
said exposing is performed in a substantially moisture free and oxygen free ambient;
said exposing is performed with the silylation agent in the vapor phase and with said substrate held at a temperature in the range from 20 to 450 degrees C., and preferably at about 150 degrees C.;
said exposing is performed for a time in a range selected from the group consisting of 30 seconds to one hour and preferably for about 60 to 300 seconds;
wherein said exposing is performed using any silylating agent which is a silane derivative selected from a group including, but not limited to mono-, di-, and tri-functional silylation agents with alkoxy, chloro, amino or silazane reactive groups attached to said at least one Si atom in its molecular make up;
said exposing is performed using a silylating agent molecule selected from the following group: bis(dimethylamino)dimethylsilane, bis(dimethylamino)methylsilane, trimethylaminodimethylsilane, tris(dimethylamino)methylsilane, and alkoxysilanes such as diethoxymethylsilane, diethoxydimethylsilane and tetramethylcyclotetrasiloxane;
said dielectric is a porous organosilicate glass material, a porous silsesquioxane, a porous SiCOH dielectric deposited by PECVD, or a porous carbon doped oxide, and said at least one etched opening consists of a plurality of single or dual damascene etched openings;
said exposing is performed in a chamber designed for PECVD deposition using a pressure between 0.001 to 100 torr of the silylating agent; and
said cluster tool has distinct chambers for one or more of silylation and dielectric cap, etch stop and barrier deposition processes.

22. A method according to claim 21 wherein said exposing is performed in a chamber designed for PECVD deposition using a pressure preferably between 1 to 10 torr and a liquid mass flow rate of the silylating agent between 10 to 5000 milligrams per minute.

23. A method according to claim 13 wherein said exposing is performed in a medium selected from the group consisting of a liquid, vapor and supercritical CO₂ phase;
when said exposing is performed liquid phase medium it is performed using any non-polar organic solvent, with the silylating agent forming a solution in said solvent, and with said substrate immersed in said liquid phase, and with an optional use of agitation;
when said exposing is performed in a non-polar organic solvent it is performed with a low surface tension, having a low flash point and boiling point, and wherein the concentration of the silylation agent is between 1% to 100% by weight of the solution;
said exposing is performed in a solvent selected from the group consisting of hexanes, heptanes, xylenes, propylene carbonates and heptanones;
when said exposing is performed in a supercritical CO₂ phase medium, said exposing is performed using said silylating agent dissolved in a supercritical CO₂ medium, and optionally in combination with a co-solvent, and wherein the silylation is performed in the temperature range between 25 degrees C. to 450 degrees C., and a pressure range from 1000 to 5000 psi, for a time interval from about 30 seconds to 1 hour;
said exposing is performed using a silylating agent which is a silane derivative selected from a group including, but not limited to mono-, di-, and tri-functional silylation agents with alkoxy, chloro, amino or silazane reactive groups attached to said at least one Si atom in its molecular make up; and
said exposing is performed using a silylation agent molecule selected from the group consisting of bis(dimethylamino)dimethylsilane, bis(dimethylamino)methylsilane, trimethylaminodimethylsilane, tris(dimethylamino)methylsilane, and the alkoxysilanes such as diethoxymethylsilane, diethoxydimethylsilane and tetramethylcyclotetrasiloxane

24. A method for a vapor phase silylation repair for at least one ultra low k dielectric film comprising:
providing an in situ cap deposition process subsequent to process seps that cause damage to said ultra low k dielectric film have occurred in a hard mask free integration process by silylation in situ before the cap dielectric deposition to repair all the cumulative damage and sealing the repaired dielectric with said cap layer.

25. A method according to claim 24 wherein there are a plurality of ultra low k dielectric films

26. A method according to claim 24 wherein said process steps that cause damage are selected from the group consisting of RIE, resist strip, wet cleans, CMP and plasma preclean before a post CMP cap deposition.

27. A method according to claim 24 of fabricating an interconnect structure on a substrate comprising:
providing a dielectric having a dielectric constant of less than 3.0 on said substrate, said dielectric having at least one etched opening located therein;
filling said at least one etched opening with at least one conductive material and then planarizing said at least one conductive material utilizing a CMP slurry to provide a planarized structure having an upper surface of said conductive material nominally coplanar with an upper surface of said dielectric, said upper surface of dielectric being exposed to said CMP slurry;
subjecting said planarized structure to a plasma preclean process; and
exposing said planarized structure to a silylating repair agent which is a derivative of a silane material with at least one silicon atom in its molecular make up and wherein at least one of the hydrogen atoms is substituted with an alkoxy-, chloro-, amino- or silazane functional group; and
forming a dielectric cap layer on said planarized structure.

28. A method according to claim 24 for fabricating an interconnect structure on a substrate comprising:
providing a dielectric having a dielectric constant of less than 3.0 on said substrate, said dielectric having at least one etched opening located therein;
filling said at least one etched opening with at least one conductive material, and then planarizing said at least one conductive material utilizing a CMP slurry to provide a planarized structure having an upper surface of said at least one conductive material nominally coplanar with an upper surface of said dielectric, said upper surface of said dielectric being exposed to said CMP slurry;
forming a self-aligned cap on said upper surface of said conductive material;
exposing said planarized structure to a silylating repair agent which is a derivative of a silane material with at least one silicon atom in its molecular make up and wherein at least one of the hydrogen atoms is substituted with an alkoxy-, chloro-, amino- or silazane functional group;
forming an optional dielectric cap layer on said self-aligned cap and said upper surface of said dielectric.
